(19) United States
(12) Patent Application Publication
(10) Pub. No.: US 2009/0185429 A1
(43) Pub. Date: Jul. 23, 2009

(54) Non-volatile memory with single floating gate and method for operating the same

(76) Inventors: Hsin Chang Lin, Chu-pei City (TW); Wen Chien Huang, Chu-pei City (TW); Ming Tsang Yang, Chu-pei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/010,121

(22) Filed: Jan. 22, 2008

(51) Int. Cl. G11C 16/06; H01L 29/788

(52) U.S. Cl. 365/185.27; 257/316; 257/E29.3

(57) ABSTRACT

A non-volatile memory with single floating gate and the method for operating the same are proposed. The non-volatile memory is formed by embedding a FET structure in a semiconductor substrate. The FET comprises a single floating gate, a dielectric, and two ion-doped regions in the semiconductor at two sides of the dielectric. The memory cell of the proposed nonvolatile memory with single floating gate can perform many times of operations such as write, erase and read by means of a reverse bias.

### FIELD OF THE INVENTION

The present invention relates to a non-volatile memory with single floating gate capable of writing and erasing many times and the method for operating the same and, more particularly, to a non-volatile memory with single floating gate capable of writing and erasing many times without the need of any control gate and the method for operating the same.

### BACKGROUND OF THE INVENTION

Memory devices can generally be classified into two categories: volatile memories and non-volatile memories. Data in volatile memories can only be kept through continual supply of power. On the contrary, data in non-volatile memories can be maintained for a very long time even if the power is cut off. Therefore, non-volatile memories have been widely used in electronic products.

In a non-volatile memory with single floating gate, two field-effect transistors (FETs) or one FET and one capacitor are generally grouped together. For example, as shown in FIG. 1, a non-volatile memory with single floating gate 100 composed of one FET and one capacitor mainly comprises a semiconductor substrate 110, a FET 120 and a capacitor 130 located on the semiconductor substrate 110, and a single floating gate 140 that electrically connects the FET 120 and the capacitor 130. In this design, the area of the whole non-volatile memory is very large to cause limit in use.

Accordingly, the present invention aims to propose a non-volatile memory with single floating gate that only requires a single FET for operation and the method for operating the same to solve the above area problem in the prior art. Moreover, the non-volatile memory with single floating gate of the present invention needs no control gate for write and erase of data, hence further reducing the complexity in design.

### SUMMARY OF THE INVENTION

An object of the present invention is to provide a non-volatile memory with single floating gate and the method for operating the same, which only requires a floating gate structure for write and read of data without the need of extra FET or capacitor, hence substantially lowering the area of non-volatile memory.

Another object of the present invention is to provide a non-volatile memory with single floating gate and the method for operating the same, in which no control gate is required for write and read of data, hence simplifying the whole design.

To achieve the above objects, the present invention provides a non-volatile memory with single floating gate, which comprises a semiconductor substrate and a FET. The FET includes a dielectric located on the surface of the semiconductor substrate, a single floating gate located on the dielectric, and two ion-doped regions located in the semiconductor substrate at two sides of the dielectric and used as a source and a drain.

The present invention also provides another non-volatile memory with single floating gate, which comprises a semiconductor substrate, a well located in the semiconductor substrate, and a FET. The FET includes a dielectric located on the well, a single floating gate located on the dielectric, and two ion-doped regions located at two sides of the dielectric and used as a source and a drain.

The present invention also provides a method for operating a non-volatile memory with single floating gate. The non-volatile memory comprises a p-type semiconductor substrate and a FET disposed on the p-type semiconductor substrate. The FET includes a floating gate and two ion-doped regions respectively disposed at two sides of the floating gate and used as a source and a drain. The method comprises the step of: applying a substrate voltage V_{sub}, a source voltage Vₛ and a drain voltage V_{d} respectively to the p-type semiconductor substrate, the source and the drain with the following conditions met:
V_{sub} is grounded and V_{d}>>Vₛ≧0 during write operation;
V_{sub} is grounded and V_{d}=Vₛ>>0 or V_{d}>Vₛ>0 during erase operation; and
V_{sub} is grounded and V_{d}>Vₛ=0 during read operation.

The present invention also provides a method for operating a nonvolatile memory with single floating gate. The nonvolatile memory comprises an n-type semiconductor, a p-well located in the n-type semiconductor substrate, and a FET disposed on the p-well. The FET includes a floating gate and two ion-doped regions respectively disposed at two sides of the floating gate and used as a source and a drain. The method comprises the step of: applying a substrate voltage V_{sub}, a p-well voltage V_{p-well}, a source voltage Vₛ and a drain voltage V_{d} respectively to the n-type semiconductor substrate, the p-well, the source and the drain with the following conditions met:
V_{sub} is connected to the power source, V_{p-well}=0, and V_{d}>>Vₛ≧0 during write operation;
V_{sub} is connected to the power source, V_{p-well}=0, and V_{d}=Vₛ>>0 or V_{d}>Vₛ>0 during erase operation; and
V_{sub} is connected to the power source, V_{p-well}=0, and V_{d}>Vₛ=0 during read operation.

### BRIEF DESCRIPTION OF THE DRAWINGS

The various objects and advantages of the present invention will be more readily understood from the following detailed description when read in conjunction with the appended drawings, in which:

FIG. 1 is a cross-sectional view of the structure of a non-volatile memory with single gate in the prior art;

FIG. 2 is a cross-sectional view of the structure of a non-volatile memory with single floating gate according to a first embodiment of the present invention;

FIG. 3(a) is a cross-sectional view of the structure of a non-volatile memory with single floating gate having four terminals according to the first embodiment of the present invention;

FIG. 3(b) is an equivalent circuit diagram of FIG. 3(a); and

FIG. 4 is a cross-sectional view of the structure of a non-volatile memory with single floating gate according to a second embodiment of the present invention.

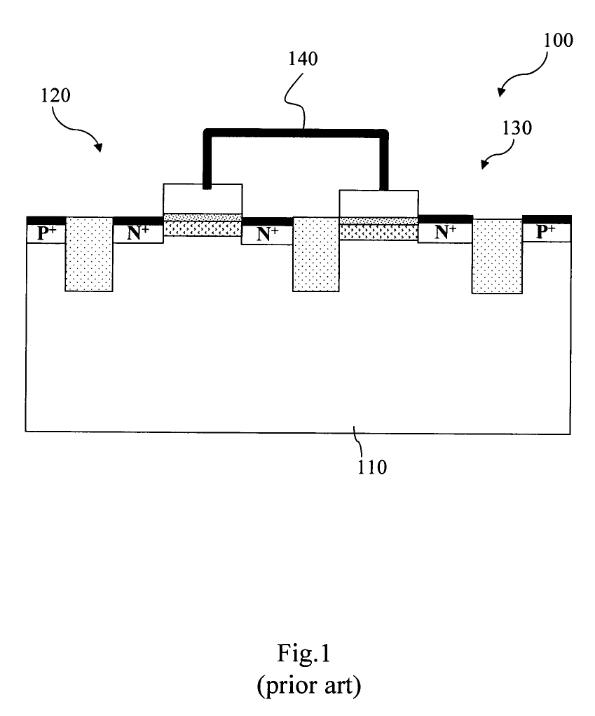

### DETAILED DESCRIPTION OF THE PREFERRED EMBODIMENTS

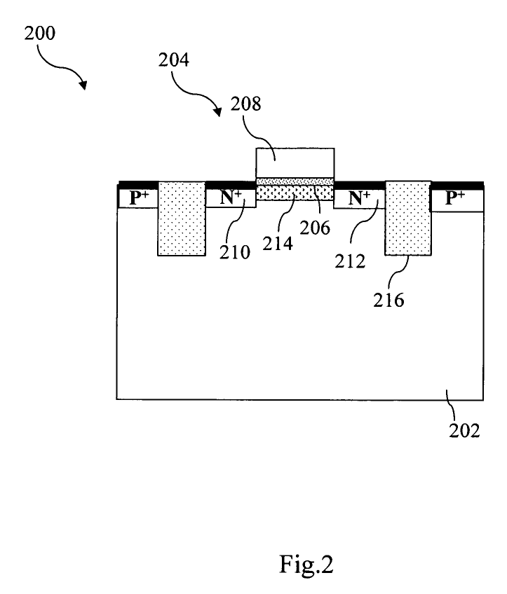

FIG. 2 is a cross-sectional view of the structure of a non-volatile memory with single floating gate according to a first embodiment of the present invention. As shown in FIG. 2, a non-volatile memory with single floating gate 200 comprises a p-type semiconductor substrate 202, and at least an NMOS field-effect FET (NMOSFET) 204 located on the p-type semiconductor substrate 202.

The NMOSFET 204 includes a dielectric 206 located on the surface of the p-type semiconductor substrate 202, a floating gate 208 disposed on the dielectric 206, two n-type ion-doped regions respectively disposed in the p-type semiconductor substrate 202 at two sides of the dielectric 206 and used as a source 210 and a drain 212, and a channel 214 located in the p-type semiconductor substrate 202 between the source 210 and the drain 212.

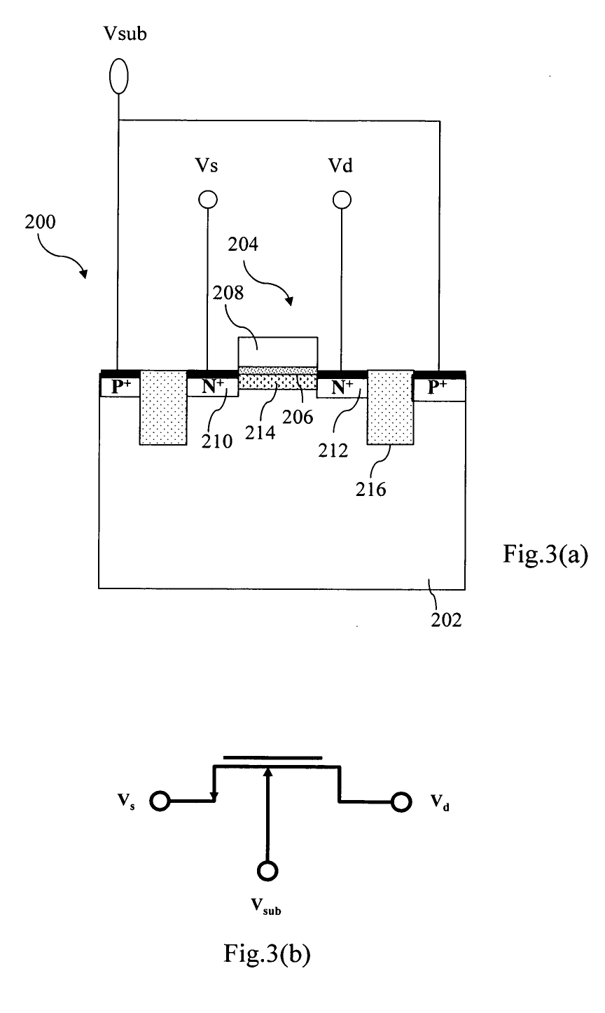

This non-volatile memory with single floating gate is a structure having three terminals. As shown in FIG. 3, these three terminals respectively connect to the source 210, the drain 212, and the p-type semiconductor substrate 202. A substrate voltage Vsub, a source voltage Vs, and a drain voltage Vd are respectively applied to the p-type semiconductor substrate 202, the source 210, and the drain 212 to form an equivalent circuit shown in FIG. 3(b).

The low-voltage operation process of this non-volatile memory with single floating gate meets the following conditions:

During write operation:
a. Vsub is grounded (=0);
b. Source/drain junction breakdown voltage >Vd>>Vₛ≧0. Because Vd >>Vs, a very large potential difference exists at the overlap location of the floating gate and the drain to generate hot holes so as to change the amount of charges of the floating gate, hence achieving the effect of writing. If the current flowing from the drain to the source is large enough, the source and the drain will be directly connected to form a short circuit, hence achieving the effect of permanent writing. The nonvolatile memory with single floating gate that is not selected meets the condition that Vₛ≠0 or is floating during write operation.

During erase operation:
a. Vsub is grounded (=0);
b. Source/drain junction breakdown voltage >Vd=Vs>>0. Because Vd=Vs>>0, the floating gate will be influenced by Vd and Vs to have a positive potential so as to attract electrons move upwards from the channel, hence achieving the effect of erasing.

Or
a. Vsub is grounded (=0);
b. Source/drain junction breakdown voltage >Vd>Vs>0. Because there is a potential difference between Vd and Vs and the floating gate is influenced by Vd and Vs to have a positive potential, hot electrons will be generated in the channel (no generation of hot holes because of insufficient potential difference). Because the floating gate has a positive potential, hot electrons will be attracted to the floating gate to achieve the effect of erasing.

During read operation:
a. Vsub is grounded (=0);
b. Vd>Vs=0. If a large amount of holes exist in the floating gate, the floating gate will be influenced by Vd to have a positive potential so as to form a channel and generate a current. The magnitude of the drain current is then based on for the decision of 0 or 1. If no hole exists in the floating gate or the source and the drain are not short-circuited, no channel will be formed, and an open circuit is thus formed.

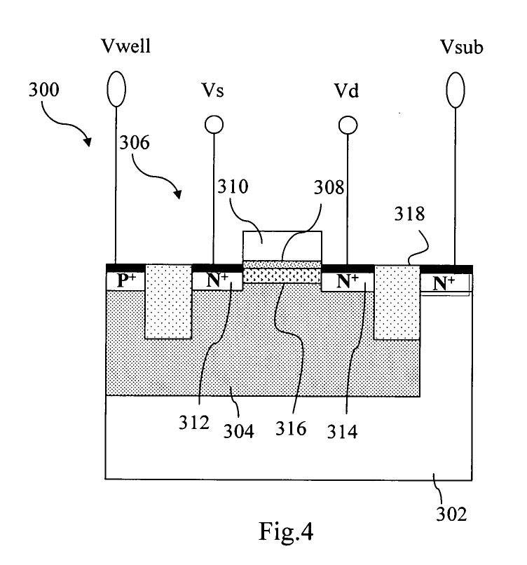

FIG. 4 is a cross-sectional view of the structure of a non-volatile memory with single floating gate according to a second embodiment of the present invention. As shown in FIG. 4, a non-volatile memory with single floating gate 300 comprises an n-type semiconductor substrate 302, a p-well 304 located in the n-type semiconductor substrate 302, and at least an NMOSFET 306 located on the p-well 304.

The NMOSFET 306 includes a dielectric 308 located on the surface of the p-well 304, a floating gate 310 disposed on the dielectric 308, two n-type ion-doped regions respectively disposed in the p-well 304 at two sides of the dielectric 308 and used as a source 312 and a drain 314, and a channel 316 located in the p-well 304 between the source 312 and the drain 314.

A substrate voltage Vsub, a p-well voltage Vp-well, a source voltage Vs, and a drain voltage Vd are respectively applied to the n-type semiconductor substrate 302, the p-well 304, the source 312, and the drain 314. The low-voltage operation process of this non-volatile memory with single floating gate meets the following conditions:

During write operation:
a. Vsub is connected to the power source, Vp-well=0;
b. Source/drain junction breakdown voltage >Vd>>Vs≧0. Because Vd >>Vs, a very large potential difference exists at the overlap location of the floating gate and the drain to generate hot holes so as to change the amount of charges of the floating gate, hence achieving the effect of writing. If the current flowing from the drain to the source is large enough, the source and the drain will be directly connected to form a short circuit, hence achieving the effect of permanent writing. The nonvolatile memory with single floating gate that is not selected meets the condition that Vₛ ≠0 or is floating during write operation.

During erase operation:
a. Vsub is connected to the power source, Vp-well=0;
b. Source/drain junction breakdown voltage >Vd=Vs>>0. Because Vd=Vs>>0, the floating gate will be influenced by Vd and Vs to have a positive potential so as to attract electrons move upwards from the channel, hence achieving the effect of erasing.

Or
a. Vsub is connected to the power source, Vp-well=0;
b. Source/drain junction breakdown voltage >Vd>Vs>0. Because there is a potential difference between Vd and Vs and the floating gate is influenced by Vd and Vs to have a positive potential, hot electrons will be generated in the channel (no generation of hot holes because of insufficient potential difference). Because the floating gate has a positive potential, hot electrons will be attracted to the floating gate to achieve the effect of erasing.

During read operation:
c. Vsub is connected to the power source, Vp-well=0;
d. Vd>Vs=0. If a large amount of holes exist in the floating gate, the floating gate will be influenced by Vd to have a positive potential so as to form a channel and generate a current. The magnitude of the drain current is then based on for the decision of 0 or 1. Or if the source and the drain are directly connected to form a short circuit, the magnitude of the drain current can also be based on for the decision of 0 or 1. If no hole exists in the floating gate or the source and the drain are not short-circuited, no channel will be formed, and an open circuit is thus formed.

The non-volatile memory with single floating gate 200 shown in FIG. 2 is formed on a p-type semiconductor substrate of silicon wafer. An isolation structure 216 is fabricated by a standard isolation module process. After fabricating the basic isolation structure 216, the channel 214 of the NMOSFET 202 is formed by ion implantation. A poly-silicon layer is then deposited, and photolithography is then performed to pattern the poly-silicon layer into the single floating gate 208. Next, ion implantation is carried out to form the source 210 and the drain 212 of the NMOSFET 202. Finally, metallization is performed to finish the fabrication of the non-volatile memory with single floating gate 200.

The non-volatile memory with single floating gate 300 shown in FIG. 4 can be fabricated by the same manufacturing process. An isolation structure 316 and the p-well 304 are first formed on the n-type semiconductor substrate of silicon wafer, and the above fabrication process of NMOSFET is then performed in the p-well 304. In the present invention, the above manufacturing process is a common CMOS manufacturing process.

To sum up, the present invention discloses a non-volatile memory with single floating gate that only requires a single FET for operation and the method for operating the same to solve the above area problem in the prior art. Moreover, the non-volatile memory with single floating gate of the present invention needs no control gate for write and erase of data, hence further reducing the complexity in the fabrication process.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A nonvolatile memory with single floating gate comprising:
a semiconductor substrate; and
a FET including:
a dielectric located on a surface of said semiconductor substrate;
a single floating gate located on said dielectric; and
two ion-doped regions located in said semiconductor substrate at two sides of said dielectric and used as a source and a drain.

2. The nonvolatile memory with single floating gate as claimed in claim 1, wherein said semiconductor substrate is p-type.

3. The nonvolatile memory with single floating gate as claimed in claim 1, wherein said ion-doped regions are doped with a first type of ions, said semiconductor substrate is doped with a second type of ions, and said first type of ions and said second type of ions are different.

4. The nonvolatile memory with single floating gate as claimed in claim 3, wherein said semiconductor substrate is p-type, while said ion-doped regions are n-type.

5. A nonvolatile memory with single floating gate comprising:
a semiconductor substrate;
a well located in said semiconductor; and
a FET including:
a dielectric located on said well;
a single floating gate located on said dielectric; and
two ion-doped regions located in said well at two sides of said dielectric and used as a source and a drain.

6. The nonvolatile memory with single floating gate as claimed in claim 5, wherein said semiconductor substrate and said ion-doped regions are doped with a first type of ions, said well is doped with a second type of ions, and said first type of ions and said second type of ions are different.

7. The nonvolatile memory with single floating gate as claimed in claim 6, wherein said semiconductor substrate and said ion-doped regions are n-type, while said well is p-type.

8. A method for operating a nonvolatile memory with single floating gate, said nonvolatile memory comprising a p-type semiconductor and a FET disposed on said p-type semiconductor substrate, said FET including a floating gate and two ion-doped regions respectively disposed at two sides of said floating gate and used as a source and a drain, said method comprising the step of:
applying a substrate voltage V_{sub}, a source voltage Vₛ and a drain voltage V_{d} respectively to said p-type semiconductor substrate, said source and said drain with the following conditions met:
V_{sub} is grounded and V_{d}>>Vₛ≧0 during write operation;
V_{sub} is grounded and V_{d}=Vₛ>>0 or V_{d}>Vₛ>0 during erase operation; and
V_{sub} is grounded and V_{d}>Vₛ=0 during read operation.

9. The method as claimed in claim 8, wherein said nonvolatile memory with single floating gate that is not selected meets the condition that Vₛ≠0 or is floating during write operation.

10. A method for operating a nonvolatile memory with single floating gate, said nonvolatile memory comprising an n-type semiconductor, a p-well located in said n-type semiconductor substrate, and a FET disposed on said p-well, said FET including a floating gate and two ion-doped regions respectively disposed at two sides of said floating gate and used as a source and a drain, said method comprising the step of:
applying a substrate voltage V_{sub}, a p-well voltage V_{p-well}, a source voltage Vₛ and a drain voltage V_{d} respectively to said n-type semiconductor substrate, said p-well, said source and said drain with the following conditions met:
V_{sub} is connected to the power source, V_{p-well}=0, and V_{d}>>Vₛ≧0 during write operation;
V_{sub} is connected to the power source, V_{p-well}=0, and V_{d}=Vₛ>>0 or V_{d}>Vₛ>0 during erase operation; and
V_{sub} is connected to the power source, V_{p-well}=0, and V_{d}>Vₛ=0 during read operation.

11. The method as claimed in claim 10, wherein said nonvolatile memory with single floating gate that is not selected meets the condition that Vₛ≠0 or is floating during write operation.
